(19) United States
(12) Patent Application Publication
(10) Pub. No.: US 2021/0082719 A1
(43) Pub. Date: Mar. 18, 2021

(54) CONDUCTIVE FLUID DISCHARGE HEAD

(71) Applicants: Kabushiki Kaisha Toshiba, Tokyo (JP); Toshiba Electronic Devices & Storage Corporation, Tokyo (JP)

(72) Inventor: Daisuke Koike, Tama Tokyo (JP)

(21) Appl. No.: 16/775,315

(22) Filed: Jan. 29, 2020

(30) Foreign Application Priority Data
Sep. 13, 2019 (JP) 2019-167311

(51) Int. Cl. H01L 21/67

(52) U.S. Cl. CPC H01L 21/6715

(57) ABSTRACT

A conductive fluid discharge head includes: a first nozzle provided at a center of the conductive fluid discharge head; a plurality of second nozzles provided outside the first nozzle; and a fluid holding container provided on fluid outlets side of the first nozzle and the second nozzle, the fluid holding container having a recessed shape. The second nozzle protrudes toward the fluid outlet side than the first nozzle by a length of equal to or greater than 50 μm and equal to or smaller than 150 μm.

### CROSS-REFERENCE TO RELATED APPLICATION

This application is based upon and claims the benefit of priority from Japanese Patent Application No. 2019-167311, filed on Sep. 13, 2019, the entire contents of which are incorporated herein by reference.

### FIELD

Embodiments described herein relate generally to a conductive fluid discharge head.

### BACKGROUND

When there is an attempt to mount a semiconductor device on a substrate and the like, a conductive fluid may be dripped at a plurality of locations on the substrate, and the semiconductor device may be placed on the dripped conductive fluid.

In recent years, a sintering paste has been used as a substitute for lead solder having a high melting point, in order to reduce an influence on an environment.

### BRIEF DESCRIPTION OF THE DRAWINGS

FIG. 1 is a cross-sectional view illustrating a conductive fluid discharge head according to an embodiment;

FIG. 2 is a cross-sectional view illustrating the conductive fluid discharge head in the embodiment;

FIGS. 3A and 3B are process diagrams of performing mounting with the conductive fluid discharge head in the embodiment;

FIGS. 4A and 4B are process diagrams of performing mounting with the conductive fluid discharge head in the embodiment;

FIGS. 5A and 5B are process diagrams of performing mounting with the conductive fluid discharge head in the embodiment;

FIG. 6 is a cross-sectional view illustrating a conductive fluid discharge head according to another embodiment; and

FIG. 7 is a cross-sectional view illustrating a conductive fluid discharge head according to still another embodiment.

### DETAILED DESCRIPTION

A conductive fluid discharge head includes: a first nozzle provided at a center of the conductive fluid discharge head; a plurality of second nozzles provided outside the first nozzle; and a fluid holding container provided on fluid outlets side of the first nozzle and the second nozzle, the fluid holding container having a recessed shape. The second nozzle protrudes toward the fluid outlet side than the first nozzle by a length of equal to or greater than 50 μm and equal to or smaller than 150 μm.

Hereinafter, embodiments of the present disclosure will be described with reference to the drawings. In the drawings attached to this specification, for easy illustrations and understandings, the scale, the dimensional ratio of the length and the breadth, and the like are appropriately changed and exaggerated from those of the components in practice.

Hereinafter, the embodiments will be described with reference to the drawings. In the drawings, the same or similar parts are denoted by the same or similar reference signs.

In this specification, the same or similar members are denoted by the same reference signs and descriptions thereof may not be repeated.

In this specification, in order to indicate positional relations between the components and the like, the upward direction in the drawings is described as “upper”, and a downward direction in the drawings is described as “lower”. In this specification, “upper” and “lower” are necessarily terms indicating the relationship with the direction of gravity.

Further, it is assumed that terms of, for example, “parallel”, “orthogonal”, “identical”, and the like, which are used in this specification and are used for specifying the shape, geometrical conditions, and the degrees thereof, and values of the length, the angle, and the like are interpreted to include a range in which the similar function may be expected, without being bound by strict meanings.

### First Embodiment

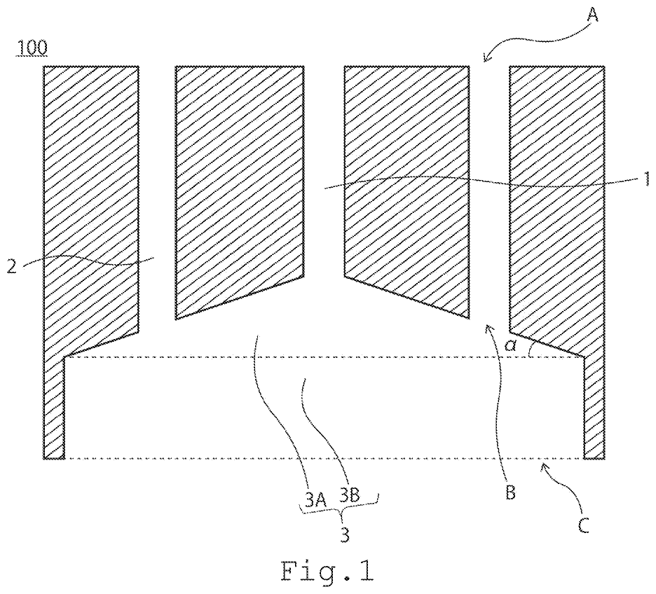

A first embodiment relates to a conductive fluid discharge head. FIG. 1 is a cross-sectional view illustrating a conductive fluid discharge head 100 according to the embodiment. The cross-sectional view of the conductive fluid discharge head 100 in FIG. 1 shows the main portion of the conductive fluid discharge head 100.

The conductive fluid discharge head 100 in FIG. 1 includes a first nozzle 1, a second nozzle 2, and a fluid holding container 3. A housing 4 of the conductive fluid discharge head 100 is a member which is made of stainless steel or the like and is excellent in machining precision.

In the embodiment, a conductive adhesive or a conductive material represented by a sintering paste or the like are used as a conductive fluid.

The first nozzle 1 is provided at the center of the conductive fluid discharge head 100. A plurality of second nozzles 2 is provided outside the first nozzle 1. Preferably, the first nozzle 1 and the second nozzles 2 are columnar nozzles. A conductive fluid supply mechanism (not illustrated) may be attached to a fluid inlet A side of the first nozzle 1 (second nozzle 2), and thus the conductive fluid supply mechanism can supply a conductive fluid to the first nozzle 1 and the second nozzle 2.

A fluid holding container 3 is provided on fluid outlets B side of the first nozzle 1 and the second nozzle 2. The fluid holding container 3 is a space in which a conductive fluid flowing out from the first nozzle 1 and the second nozzle 2 is held. A side of the fluid holding container 3 on an opposite side of the first nozzle 1 and the second nozzle 2 is totally opened. Since the conductive fluid stays in the fluid holding container 3, it is possible to transfer the conductive fluid staying in the fluid holding container 3 to the substrate side by causing the opening side to abut on the substrate and the like. Preferably, an opening surface C of the fluid holding container 3 on an opposite side of the first nozzle 1 and the second nozzle 2 is a flat surface. Since the opening surface C is the flat surface, it is possible to transfer the conductive fluid to the substrate side without breaking the shape of the fluid holding container 3.

Diameters of the first nozzle 1 and the second nozzle 2 are not particularly limited. The diameter of the first nozzle 1 may be equal to or different from the diameter of the second nozzle 2.

Preferably, the fluid holding container 3 includes a frustum-like region 3A and a prismatic or cylindrical region 3B as partitioned by broken lines (virtual lines).

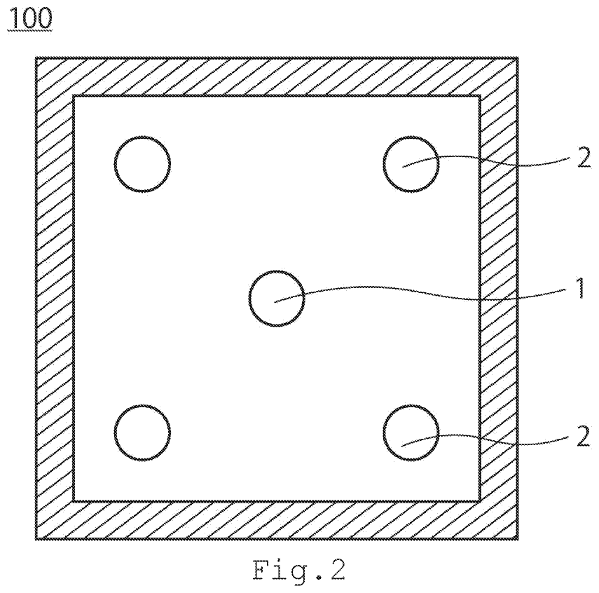

The shape of the opening surface C of the fluid holding container 3 is a circle including an ellipse or a polygon. It is possible to appropriately select the shape of the opening surface C and arrangement of the nozzles with corresponding to the shape and the size of a semiconductor device to be mounted. Preferably, the shape of the opening surface C of the fluid holding container is similar to the shape of the semiconductor device to be mounted or is similar to the shape of a pad in the semiconductor device to be mounted. In the first embodiment, as illustrated in the cross-sectional view in FIG. 2, the opening surface C of the fluid holding container 3 has a square shape and thus is suitably used for mounting a square semiconductor device.

Generally, the conductive fluid used for mounting a semiconductor device is dropped on the substrate with very high precision. Thus, the height of a nozzle in a discharge head including a plurality of nozzles which has the equal height and is used for dropping the same amount of fluid has high precision with an error which is equal to or smaller than about 10 μm.

However, if the same amount of conductive fluid is regularly dropped onto the substrate, and then a semiconductor device is mounted on the substrate, when the semiconductor device is pressed against the substrate side, voids are easily generated, and a spread portion and a not-spread portion (difficult to spread) are provided when the conductive fluid. Thus, an air may remain between a portion of the pad on the substrate side of the semiconductor device and the substrate, and voids may be generated. If the void is generated, it is difficult for a large current to flow, and heat dissipation from the pad is degraded.

If the conductive fluid of an amount as appropriate as it is difficult to generate voids is transferred onto the substrate by using a discharge head which causes the conductive fluid to be transferred onto a film having a uniform thickness on the substrate, with corresponding to the size of the semiconductor device, it is easy to expand conductivity to the outer circumference side of the semiconductor device. If the conductive fluid is transferred onto the substrate in the above manner, the conductive fluid tends to crawl up to the upper surface side (side opposite to the substrate side) of the semiconductor device. The thickness of the semiconductor device is reduced in order to reduce resistance, and thus the conductive fluid tends to further crawl up to the upper surface of the semiconductor device. In a case where the semiconductor device is mounted in a form in which a large current flows from the upper surface of the semiconductor device toward the lower surface thereof, the semiconductor device is short-circuited by crawling up.

If the conductive fluid is set to be thick at the center of the conductive fluid to be transferred, and the thickness is set to be reduce toward an outer circumferential direction, it is possible to prevent generation of a void and an occurrence of crawling. Preferably, the thickness of the conductive fluid to be transferred is set to be reduced from the center to the outside. Preferably, the second nozzle 2 protrudes toward the fluid outlet B more than the first nozzle 1. If the second nozzle 2 protrudes toward the fluid outlet B much larger than the first nozzle 1, the transferred conductive fluid is concentrated on the center of the substrate, and the conductive fluid is small on the edge side. Thus, the void is likely to be generated. In order to set an inclination in thickness to be appropriate, the second nozzle 2 preferably protrudes toward the fluid outlet B side than the first nozzle 1 by a length of equal to or greater than 50 μm and equal to or smaller than 150 μm.

If the length of the second nozzle 2 protruding with respect to the first nozzle 1 varies largely, the shape of the conductive fluid to be transferred does not have symmetry, and thus it is easy to generate voids or to crawl up. Thus, preferably, the length of the second nozzle 2 protruding with respect to the first nozzle 1 is within ±5 μm of an average value of the length of the second nozzle 2 protruding with respect to the first nozzle 1.

A plurality of second nozzles 2 is disposed outside the first nozzle 1. If the second nozzles 2 are randomly arranged, the conductive fluid staying in the fluid holding container 3 tends to be biased. Thus, as illustrated in the cross-sectional view of the conductive fluid discharge head 100 in FIG. 2, it is preferable that the second nozzles 2 are arranged on the circumference centering on the first nozzle 1. FIG. 2 is a cross-sectional view of the conductive fluid discharge head 100 at a, A-A′ position in FIG. 1. From the same viewpoint, it is preferable that a distance between the first nozzle 1 and each of the second nozzles 2 is equal.

It is preferable that the second nozzle 2 is disposed on each circumference centering on the first nozzle 1, and the distance between the first nozzle 1 and the second nozzle 2 disposed on each circumference is equal. Preferably, when the number of second nozzles 2 is set to n, the second nozzle 2 and the fluid holding container 3 are n-fold rotational symmetry around a columnar axis direction of the first nozzle 1.

In the cross-sectional view in FIG. 1, the nozzle side and the fluid holding container 3 side similarly have a rectangular shape. However, the embodiment is not limited to a form in which the nozzle side and the fluid holding container 3 side have the similar shape as with the cross-sectional shape in FIG. 1. For example, a form in which the nozzle side has a cylindrical shape, and a rectangular fluid holding container 3 is connected to the cylindrical tip end is provided. Since the nozzle is also located on the fluid holding container 3, in the embodiment, a boundary between the nozzle side and the fluid holding container 3 is not clearly determined.

From a viewpoint of transferring the conductive fluid having the above-described shape, preferably, the fluid holding container 3 includes the frustum-like region 3A, and the center of the upper surface of the fluid holding container 3 is located on the center of the tip end of the first nozzle 1. Preferably, the upper surface of the frustum shape corresponds to the upper surface of the fluid holding container 3, and the fluid holding container 3 expands from the first nozzle 1 side toward the opening surface C. The frustum shape 3A is either a truncated cone or a truncated pyramid. The frustum shape is not limited to an exact frustum shape. In the embodiment, even in a case where the shape of the upper surface is different from the shape of the bottom surface, the shape is handled as the frustum shape.

Preferably, an angle α formed by the oblique side and the bottom surface of the frustum shape is equal to or greater than 0 degrees and equal to or smaller than 60 degrees. A frustum shape hardly having an angle is preferable. If the angle is large, a difference between the thickness at the center of the transferred conductive fluid and the thickness on the edge side is large, and thus voids are easily generated on the edge side when the semiconductor device is mounted. If the angle is too small, the difference between the thickness at the center of the transferred conductive fluid and the thickness on the edge side is too small. Thus, if the conductive fluid of an amount causing the generation of voids to be prevented is transferred, the conductive fluid tends to crawl up from the edge of the semiconductor device. If the angle is too small, it is difficult to expand the conductive fluid in the vicinity of the center. Thus, voids may be easily generated. Thus, it is more preferable that the angle α formed by the oblique side and the bottom surface of the frustum shape is equal to or greater than 0 degrees and equal to or smaller than 60 degrees.

It is preferable that the second nozzle 2 is a columnar nozzle having a diagonal notch at a tip end thereof, and the oblique side of the frustum-like region 3A is along the tip end of the second nozzle 2, at which the diagonal notch is provided. That is, preferably, the oblique surface of the frustum-like region 3A is a flat surface. A small unevenness generated by machining the oblique surface of the frustum-like region 3A is allowable. However, if not the frustum-like region 3A but a shape having obvious irregularities on the oblique surface like a staircase pyramid is provided, a portion of an angle of the step easily acts as the cause of the void. In addition, since a frustum shape having a very shallow angle is provided, it is difficult to form such a complex shape.

Preferably, the prismatic or cylindrical region 3B is provided on the opening side of the fluid holding container 3. The frustum-like region 3A is a region having a small volume due to a shallow angle. Preferably, the prismatic or cylindrical region 3B is provided such that the fluid holding container 3 holds the conductive fluid of an amount sufficient for mounting the semiconductor device.

If the height of the center of the fluid holding container 3 is set to H1, H1 represents the sum of the height of the frustum-like region 3A and the height of the prismatic or cylindrical region 3B. If the height of the edge side of the fluid holding container 3 is set to H2, H2 represents the height of the prismatic or cylindrical region 3B. Preferably, H1−H2 being the height of the frustum-like region 3A is equal to or greater than 0 μm and equal to or smaller than 9000 μm. As described above, with the center having a low height, it is possible to prevent generation of the void and the occurrence of crawling.

Preferably, H1 and H2 satisfy 0≤(H1−H2)/H1≤1. Since H1 and H2 satisfy the above range, it is possible to favorably adhere the semiconductor device and to prevent generation of the void and the occurrence of crawling.

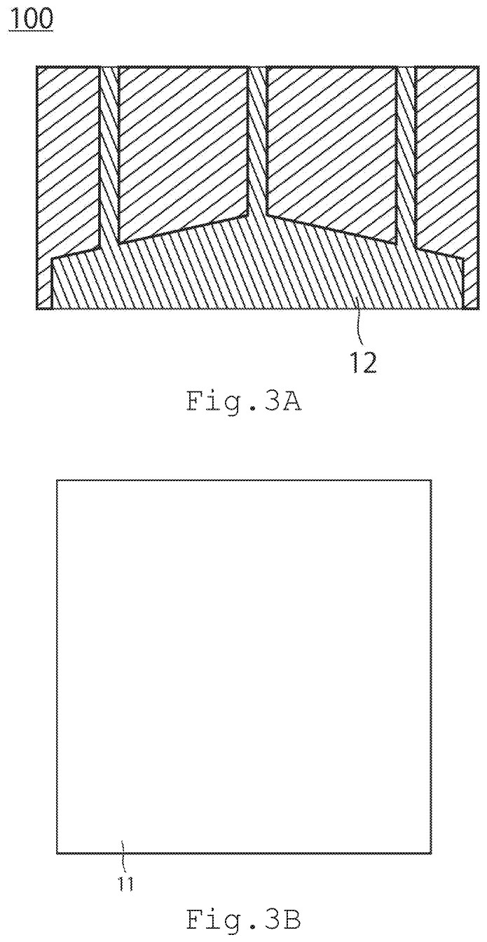

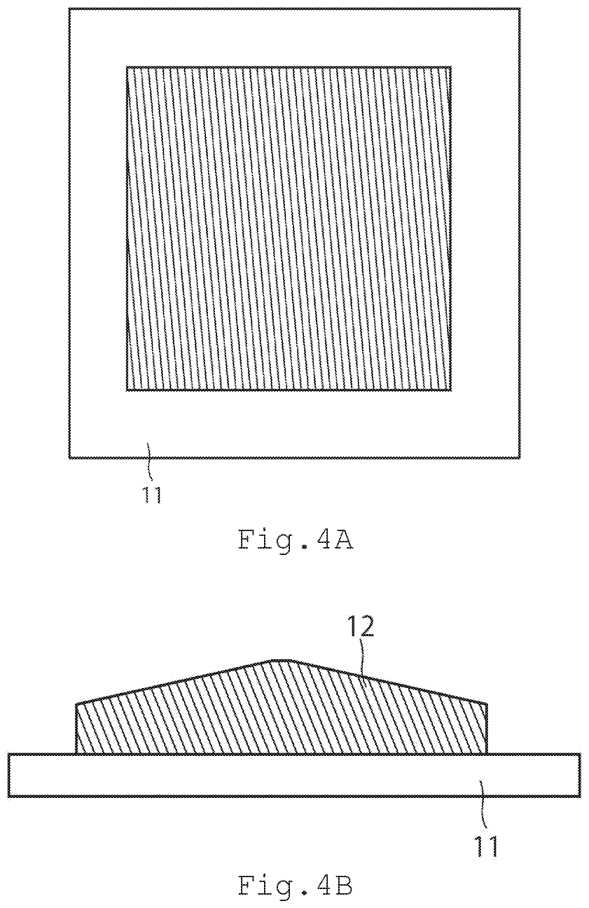

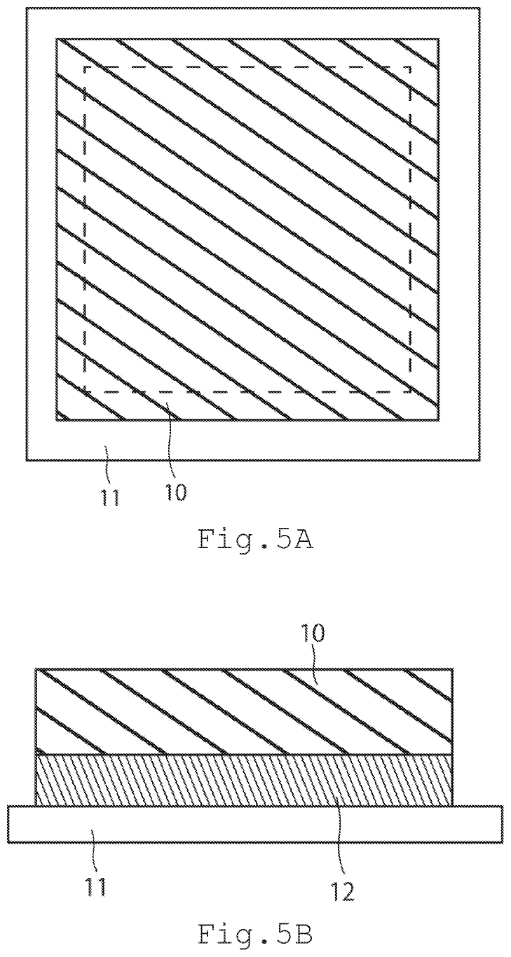

Next, a method of mounting the semiconductor device 10 on a substrate 11 using the conductive fluid discharge head 100 in the embodiment will be described with FIGS. 3A to 5B which are process diagrams of performing mounting with the conductive fluid discharge head in. Regarding the cross-sectional view in FIGS. 3A to 5B, FIG. 3A is a cross-sectional view of the conductive fluid discharge head 100. FIG. 3B, FIG. 4A, and FIG. 5A are a top view of the substrate 11. FIG. 4B and FIG. 5B are a cross-sectional view of the substrate 11.

FIG. 3A is a cross-sectional view of the conductive fluid discharge head 100. FIG. 3B is a top view of the substrate 11. A conductive fluid 12 is held in the fluid holding container 3 of the conductive fluid discharge head 100. With the conductive fluid supply mechanism (not illustrated) causing the conductive fluid 12 to stay in the fluid holding container 3, the conductive fluid flows in the nozzle. If the fluid holding container 3 is full, an operation of the conductive fluid supply mechanism is stopped.

As illustrated in the cross-sectional view in FIG. 4A, the conductive fluid 12 in the conductive fluid discharge head 100 is transferred onto the substrate 11. FIG. 4B is a top view of the substrate 11 onto which the conductive fluid 12 is transferred. FIG. 4A is a cross-sectional view of the substrate 11 onto which the conductive fluid 12 is transferred. The fluid holding container 3 in the conductive fluid discharge head 100 is empty. Thus, the conductive fluid 12 having a slightly high center is formed on the substrate 11 side, as illustrated in FIGS. 4A and 4B. In order to prevent the occurrence of crawling, the conductive fluid 12 preferably has an area slightly smaller than the semiconductor device 10.

Then, as illustrated in the cross-sectional view in FIG. 5, the semiconductor device 10 is placed on the conductive fluid 12. FIG. 5A is a top view in which the semiconductor device 10 is placed on the substrate 11 onto which the conductive fluid 12 is transferred. FIG. 5B is a cross-sectional view in which the semiconductor device 10 is placed on the substrate 11 onto which the conductive fluid 12 is transferred. As illustrated in FIG. 5A, the semiconductor device 10 is pressed against the substrate 11 side during placement, and thus the conductive fluid 12 provided in the original region indicated by a broken line is expanded. Thus, the conductive fluid 12 expands to the edge side of the semiconductor device 10. If the pressure is large, crawling occurs. Thus, it is preferable that the conductive fluid expands with small pressure to have a shape approximate to the shape of the semiconductor device 10 or the pad. Preferably, expansion is performed even with small pressure such that the thickness of the conductive fluid 12 is uniform. If the thickness of the center of the conductive fluid 12 is set to be slightly thick, even though the conductive fluid 12 does not expand much, it is possible to suppress generation of voids and the occurrence of crawling of the conductive fluid 12, as illustrated in the cross-sectional view in FIG. 5C. The semiconductor device 10 can be favorably mounted on the substrate 11, if necessary, by performing sintering or the like to harden the conductive fluid 12.

### Second Embodiment

A second embodiment relates to a conductive fluid discharge head. The second embodiment is a modification example of the conductive fluid discharge head in the first embodiment. Regarding a component, a method, and the like which are common between the second embodiment and the first embodiment, descriptions will not be repeated.

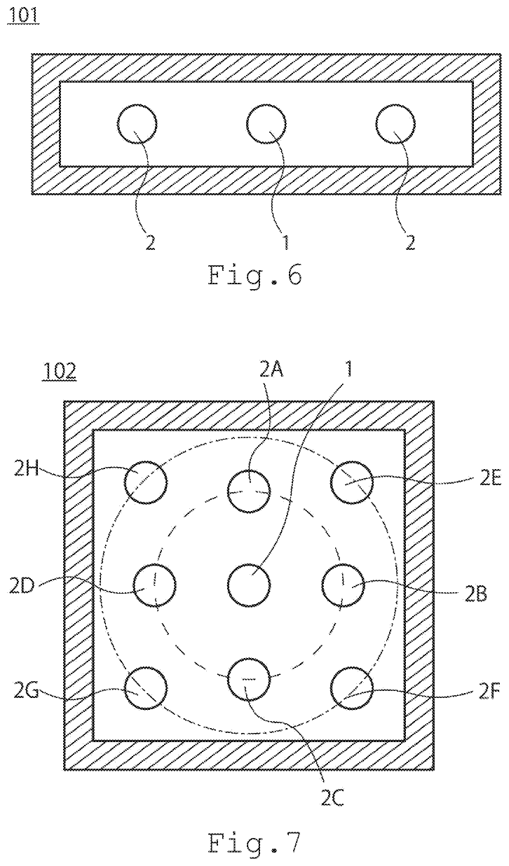

FIG. 6 is a cross-sectional view illustrating a conductive fluid discharge head 101 according to the second embodiment. In the conductive fluid discharge head 100 in the first embodiment, a square shape is employed as the shape of the opening surface C of the fluid holding container 3 such that the square conductive fluid 12 can be transferred. In the second embodiment, a semiconductor device includes a rectangular pad. Thus, in the second embodiment, the opening surface C is set to be rectangular with corresponding to the shape of the pad of the semiconductor device, and the arrangement of the second nozzle 2 is changed from that in the conductive fluid discharge head 100 in the first embodiment.

In the conductive fluid discharge head 101, two second nozzles 2 are provided to interpose the first nozzle 1 at the center. If the second nozzles 2 are disposed such that a distance between the first nozzle 1 and each of the second nozzles 2 is equal, it is possible to dispose the second nozzle 2 on the circumference centering on the first nozzle 1, similar to the first embodiment. Since the region 3A on a side opposite to the opening side of the fluid holding container 3 has a quadrangular frustum shape in which a rectangle having a relatively large aspect ratio as in FIG. 6 is used as the bottom surface, it is possible to transfer the rectangular conductive fluid 12 having a relatively large aspect ratio onto the substrate. Thus, it is possible to suppress generation of voids and the occurrence of crawling and to mount the semiconductor device approximate to the rectangle.

### Third Embodiment

A third embodiment relates to a conductive fluid discharge head. The third embodiment is a modification example of the conductive fluid discharge head in the first embodiment. Regarding a component, a method, and the like which are common between the second embodiment and the first embodiment, descriptions will not be repeated.

FIG. 7 is a cross-sectional view illustrating a conductive fluid discharge head 102 according to the third embodiment. In the third embodiment, a semiconductor device includes a square pad larger than that in the first embodiment. In the third embodiment, the arrangement of the second nozzle 2 is changed from that in the conductive fluid discharge head 100 in the first embodiment.

In the conductive fluid discharge head 102, second nozzles 2 are disposed on two circumferences centering on the first nozzle 1 at the center. The second nozzles 2A, 2B, 2C, and 2D are disposed on the inner circumference indicated by a broken line (virtual line). The second nozzles 2E, 2F, 2G, and 2H are disposed on the outer circumference indicated by a one dot chain line (virtual line). In a case where the second nozzles are disposed on one circumference, the second nozzles 2 are disposed on the same circumference. Thus, even though the area of the opening surface C of the fluid holding container 3 is large, it is possible to cause the conductive fluid to stay with corresponding to the shape of the fluid holding container 3. Even in a case where the second nozzles 2 are disposed on the same circumference, it is possible to transfer the conductive fluid 12 having a slightly thick center portion onto the substrate 11. Thus, similar to other embodiments, it is possible to suppress the generation of voids and the occurrence of crawling and to mount the semiconductor device 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A conductive fluid discharge head comprising:
a first nozzle provided at a center of the conductive fluid discharge head;
a plurality of second nozzles provided outside the first nozzle; and
a fluid holding container provided on fluid outlets side of the first nozzle and the second nozzle, the fluid holding container having a recessed shape,
wherein the second nozzle protrudes toward the fluid outlet side than the first nozzle by a length of equal to or greater than 50 μm and equal to or smaller than 150 μm.

2. The head according to claim 1, wherein the second nozzle is disposed on a circumference centering on the first nozzle.

3. The head according to claim 1, wherein the fluid holding container has a frustum shape, and
a center of an upper surface of the fluid holding container is located at a tip end of the first nozzle.

4. The head according to claim 1, wherein the fluid holding container has a frustum shape, and
an angle formed by an oblique side and a bottom surface of the frustum shape is equal to or greater than 0 degrees and equal to or smaller than 60 degrees.

5. The head according to claim 1, wherein a tip end of the second nozzle is a columnar nozzle having a diagonal notch,
the fluid holding container has a frustum shape, and
an oblique side of the frustum shape is along the tip end of the second nozzle which has the diagonal notch.

6. The head according to claim 1, wherein a height of a center of the fluid holding container is H1,
a height of an edge side of the fluid holding container is H2, and
H1 and H2 satisfy 0≤(H1−H2)/H1≤1.

7. The head according to claim 1, wherein a length of the second nozzle protruding with respect to the first nozzle is within ±5 μm of an average value of a length of the second nozzle protruding with respect to the first nozzle.

8. The head according to claim 2, wherein when a number of the second nozzle is n, the second nozzle and the fluid holding container are n-fold rotational symmetry around a columnar axis direction of the first nozzle.
